(19) United States
(12) Patent Application Publication
(10) Pub. No.: US 2024/0396327 A1
(43) Pub. Date: Nov. 28, 2024

(54) ELECTROSTATIC DISCHARGE PROTECTION CIRCUIT WITH LOW-LEAKAGE FOR LARGE VOLTAGE SWING OF POSITIVE CURRENT

(71) Applicant: Intel Corporation, Santa Clara, CA (US)

(72) Inventors: Krzysztof Domanski, Neubiberg (DE); Harshit Dhakad, Bangalore (IN)

(73) Assignee: Intel Corporation, Santa Clara, CA (US)

(21) Appl. No.: 18/201,592

(22) Filed: May 24, 2023

(51) Int. Cl. H02H 9/04; H01L 27/02

(52) U.S. Cl. CPC H02H 9/04; H01L 27/02

(57) ABSTRACT

An electrostatic discharge protection circuit, device, system, and apparatus has low-leakage for a large voltage swing of positive current.

### BACKGROUND

Semiconductor devices such as logic transistors are often susceptible to damage due to unintentional electrostatic discharge (ESD) events that occur during manufacturing of the semiconductor chips and packaging, as well as during normal use. ESD protection clamp circuits are used to prevent component damage on the integrated circuits of the semiconductor devices. The ESD clamps shunt ESD currents so that ideally the semiconductor devices still only receive current with voltages within acceptable ranges despite the ESD, thereby preventing damage to the devices. As smaller transistors are being used, however, the smaller devices have smaller input-output (IO) operating voltages. This increases the size of the range or voltage swing that needs to be handled by the ESD clamps to prevent damage to the smaller semiconductor devices.

### BRIEF DESCRIPTION OF THE DRAWINGS

The implementations of the disclosure will be understood more fully from the detailed description given below and from the accompanying drawings of various implementations of the disclosure, which, however, should not be taken to limit the disclosure to the specific implementations, but are for explanation and understanding only.

FIG. 1 is a schematic diagram of an example device with an electrostatic discharge (ESD) protection circuit according to at least one of the implementations herein;

FIG. 2 is a schematic diagram of another example device with ESD protection circuits according to at least one of the implementations herein;

FIG. 3 is a schematic diagram of details of an example ESD clamp of the ESD protection circuit of FIG. 2 and according to at least one of the implementations herein;

FIG. 4 is a schematic diagram of an example of a parasitic bipolar junction transmitter (BJT) circuit structure of the ESD clamp of FIG. 3 according to at least one of the implementations herein;

FIG. 5 is a schematic diagram of a top view of example semiconductor structure of the ESD clamp of FIG. 2 and according to at least one of the implementations herein;

FIG. 6 is a schematic diagram of a side cross-sectional view of the semiconductor structure of an ESD clamp according to at least one of the implementations herein;

FIG. 7A is a schematic diagram of another example ESD clamp of the ESD protection circuit of FIG. 2 and according to at least one of the implementations herein;

FIG. 7B is a schematic diagram of an example of the parasitic bipolar junction transmitter (BJT) circuit structure of the ESD clamp of FIG. 7A according to at least one of the implementations herein;

FIG. 8 is a schematic diagram of another side cross-sectional view of the semiconductor structure with another ESD clamp according to at least one of the implementations herein;

FIG. 9 is a schematic diagram of an example semiconductor device circuit with ESD clamp circuits and a resistance-capacitance (RC) metal-oxide semiconductor (MOS) circuit structure according to at least one of the implementations herein;

FIG. 10 is a schematic diagram of an example ESD clamp of the ESD circuit of FIG. 9 and according to at least one of the implementations herein;

FIG. 11 is a schematic diagram of an example system, in accordance with at least one implementation herein; and

FIG. 12 is a schematic diagram of an example mobile computing platform and a data server machine employing an IC having an ESD clamp, in accordance with at least one implementation herein.

### DETAILED DESCRIPTION

One or more implementations of electrostatic discharge protection circuits or clamps are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary implementations. Further, it is to be understood that other implementations may be utilized and structural and/or logical changes may be made without departing from the scope of claimed subject matter. It also should be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the presently disclosed devices, systems, methods, circuits and so forth may be practiced without these specific details. In some instances, well-known methods and devices are shown in block diagram form, rather than in detail, to avoid obscuring the claimed features. Reference throughout this specification to “an implementation” or “one implementation” or “some implementations” refers to a particular feature, structure, function, or characteristic described in connection with the implementation that is included in at least one implementation herein. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.

Note that in the corresponding drawings of the implementations, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary implementations to facilitate easier understanding of a circuit or a logical unit. Any represented signal, as dictated by design needs or preferences, may actually comprise one or more signals that may travel in either direction and may be implemented with any suitable type of signal scheme.

As used in the description and the appended claims, the singular forms “a”, “an” and “the” are intended to include the plural forms as well, unless the context clearly indicates otherwise. It also will be understood that the term “and/or” as used herein refers to and encompasses any and all possible combinations of one or more of the associated listed items.

The term “device” may generally refer to an apparatus according to the context of the usage of that term. For example, a device may refer to a stack of layers or structures, a single structure or layer, a connection of various structures having active and/or passive elements, etc. Generally, a device is a three dimensional structure with a plane along the x-y direction and a height along the z direction of an x-y-z Cartesian coordinate system. The plane of the device also may be the plane of an apparatus which comprises the device.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship). Further, “coupled”, “couple”, and “coupling” herein refers to conductive or electrical coupling unless the context suggests otherwise.

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies.

The terms “left,” “right,” “front,” “back,” “top,” “bottom”, “up”, and “down”, and the like in the description and in the claims, if any, are used for descriptive purposes and not necessarily for describing permanent relative positions. The meaning of “in” includes “in” and “on.”

The term “adjacent” here generally refers to a position of a thing being next to (e.g., immediately next to or close to with one or more things between them) or adjoining another thing (e.g., abutting it). The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used throughout this description, and in the claims, a list of items joined by the term “at least one of” or “one or more of” or “or” can mean any combination of the listed terms. For example, the phrase “at least one of A, B or C” can mean A; B; C; A and B; A and C; B and C; or A, B and C.

The term “circuit” or “module” may refer to one or more passive and/or active components that are arranged to cooperate with one another to provide a desired function. The term “signal” may refer to at least one current signal, voltage signal, magnetic signal, or data/clock signal.

The term “interconnect” herein refers to any conductive feature intended to transmit electricity or signals such as wires or that may form metallization on an integrated circuit or circuit board including traces, caps, contacts, vias, pads, landings, and so forth to transmit electrical current and/or data.

Also, those elements of the figures having the same reference numbers (or names) as the elements of any other figure can operate or function in any manner similar to that described, but are not limited to such.

A permissible signal overshoot or transient voltage swing for a semiconductor transistor depends on the specific technology area and applications, and in turn the specific semiconductor structures and circuits being used. A number of technology areas have ESD specifications specific to a certain generation of transistors being used. For example, permissible ESD overshoot specifications are provided for communication technologies including 5G or RADAR as part of antenna specifications for example. This includes high frequency (HF) transmission (TX) semiconductor applications with 16 nm fin field effect transistor (finFET) pitch (or 16FF generation). This TX semiconductor specification provides that TX semiconductor devices should be able to handle a voltage swing of up to +/−2.5V applied at an integrated circuit pad.

The voltage swing includes the operating voltage that can be handled by the semiconductor devices being protected (the “victims”) plus the amount of voltage that can be shunted by the ESD protection clamps. For example, conventional fail-safe dual pad to VDD (PD) mode and pad to VSS (PS) mode ESD metal oxide semiconductor field effect transistor (MOSFET) clamps are provided for semiconductor victim devices with operating voltages of 1.8 volts while using 16FF finFET or older technology, and these known ESD clamps can shunt up to 0.7 volts for a total of the specified +/−2.5 volts. A fail-safe ESD circuit refers to an ESD circuit that can be off with no current flowing through the ESD clamp with VDD voltage switched off.

However, the smaller transistors of N5 and/or N3 generation technology often have an operating voltage of 1.2 volts. In this case, when the known ESD clamp topologies are arranged with 1.2V devices on circuits to protect the smaller transistors, such as with the N5 or N3 technology, the known ESD clamps can only handle signal swings of up to a mere +/−1.9 volts, falling far short of the specified +/−2.5V. This can result in a reduction of a fail-safe voltage specification (or maximum) for the known ESD from 2.5V to 1.9V, or can limit the circuits to 1.8V devices with which the +/−2.5V fail-safe ESD can be safely constructed.

In addition, certain circuits such as a real-time clock (RTC) circuit also have difficulty with ESD protection due to the electrical ESD specifications of the smaller semiconductor technologies. For example, an RTC circuit often is directly connected to a battery on a PC motherboard and drains the battery in an external power-off state. The conventional ESD protection clamp of a 3.3V supply rail in N6 technology is an RTC power clamp made of stacked 1.8V n-channel IO devices with a shared-diffusion layout style (where a source of an upper device is used as a drain of a lower device in the stack) within the same well (a dual-well configuration). This ESD arrangement attempts to provide up to 6 amp current discharge model (CDM) current protection with low clamping voltage during ESD stress. This type of circuit, however, has voltage leakage from a source operating at 3.3V VDD to bulk, which dominates the total leakage. Resulting current leakage with the conventional RTC clamp can be up to 9 μA.

The specification for stand-by current leakage, however, for conventional RTC circuits of N6 technology is less than 300 nA, and a current leakage budget for an ESD power-clamp, at the supply voltage mentioned, to be no more than 50 nA, which is 180 times less than the 9 μA current leakage of the known RTC circuits as described. The result is significant damage to N6 and smaller technology victim devices.

To resolve these issues, a disclosed semiconductor device has ESD circuitry that can shunt or dissipate current with a greater amount of swing voltage than conventional ESDs and for integrated circuits using smaller transistors, such as 6, 5, or sub-5 nm finFET technology that may include HF switches for example, and with smaller operating voltages, such as 1.2 volts. This may be arranged to meet specified overshoot voltage swing capacities that also can be used with the larger 1.8 volt transistor devices. Particularly, a semiconductor device has at least one ESD circuit with an ESD clamp. The ESD clamp may comprise a parasitic bipolar junction transistor (BJT) structure that comprises back to back (or anti-parallel) diodes with anodes connected through a common base node. The term “back to back” and “anti-parallel” herein refers to diodes coupled to each other in series at their anodes.

Also, it should be noted that the term parasitic herein refers to an electrical circuit element that effectively or functionally represents or resembles other electrical components. For example, a parasitic BJT structure represents, or may be formed by, two P-N junction diodes connected by a common node. Herein, the diodes in turn also may be parasitic rather than physical. In one particular example, the anti-parallel diodes may represent P-N junctions between wells of the present semiconductor structure. For example, one of the diodes may represent the P-N junction between an isolated p-type well (iso-p-well or just p-well) and a deep n-type well (or just n-well or n-band), while the other diode may represent the P-N junction between the deep n-well (or n-band) and a p-type substrate in a triple well arrangement. The diodes also may be referred to as MOSFET diodes because the BJT, and in turn the anti-parallel diodes, also may represent a MOSFET with source, drain, and gate regions or structures that control the flow of electrons and holes within the wells.

The parasitic BJT circuit structure also may have a tap within the p-well and/or around the emitter and/or collector regions, while an n-well guard ring (also referred to as a contact ring) is placed around the iso-p-well to electrically bias the deep n-well in order to provide voltage bias to the deep-n-well and isolation of the iso-p-well from p-bulk.

While a single ESD clamp may be used, by example forms herein, a device with victim circuitry and semiconductor devices to be fully protected may have two parallel ESD clamps to protect from current of two directions (or polarities). One clamp may be a pad to VDD (PD) mode ESD clamp that shunts positive current or discharge from a pad (or IO interconnect) conductively coupled to the clamps and devices to be protected and coupled to a VDD interconnect, and then through the PD ESD clamp to a VSS interconnect. The other ESD clamp may be a pad to VSS (PS) mode ESD clamp that shunts negative current or discharge from the VSS interconnect, through the PS ESD clamp to the VDD interconnect, and then to the pad. It will be noted that the positive and negative currents or discharges can be achieved intentionally for testing by a negative zap or stress (to get a positive current), or a positive zap or stress (to get a negative current) of a charged device model (CDM) and applied at the pad.

The base of the parasitic BJTs may be soft tied to the VSS interconnect by coupling a resistor to the base and the VSS interconnect. This may be accomplished by at least coupling a resistor to the deep n-well in the semiconductor structure. Optionally, another base resistor may be coupled between the base and the VSS interconnect for the PD ESD clamp, while the optional base resistor may be coupled between the base and the emitter for the PS ESD clamp. These resistors are used to better ensure triggering of the BJT.

Such a PD and PS input-output (IO) dual clamp arrangement may provide failsafe protection while shunting both positive and negative current or discharge as needed. Such ESD clamp arrangement may be provided for HF TX switches in N5 or N3 1.2V technology for example, with a maximum IO signal swing of 2.5V and when VDD equals 0V for example. This also includes supporting negative signal swing, and with signals oscillating to negative voltage smaller or equal to 2.5V for ESD protection built of the 1.2V devices.

In addition, the PD or PS clamps can provide low leakage less than 10 nA in room temperature (RT). The capacitive load at HF PAD from ESD is about 200 fF at 4 A as tested as a CDM target current, and which is scalable for the capacitive load for other target current amounts.

In an alternative two stage ultra-low leakage implementation, a first stage uses an arrangement of the PD mode clamp (referred to as a higher voltage clamp), while a second stage uses a resistor-capacitor (RC) MOS low-leakage clamp (referred to as a lower voltage clamp or RC-MOS clamp) in parallel to the PD mode clamp to achieve ultra-low leakage. Specifically, the PD mode clamp here may have a parasitic BJT NPN device stacked in series with a diode for further leakage suppression. The PD mode clamp may approach driving about 95% of relatively large amounts of positive current of CDM stress triggered by relatively higher voltage levels (compared to the voltage (and current) levels handled by the RC-MOS clamp). For example, the PD mode clamp 910 can dissipate 5.7 A of a 6 A CDM target zap.

For reduction of the clamping voltage from the PD mode clamp, the first and second stage ESD protection clamps are separated by a ballast resistor of 10 Ohms, in one example, on the VDD (or IO) interconnect to reduce the amount of current flowing to the RC-MOS clamp thereby reducing the size of the RC-MOS clamp needed to shunt the transient current. The internal circuitry experiences clamping voltage reduced by a voltage drop at the ballast resistor.

The ESD RC-MOS clamp of the second stage has two stacked or series RC MOSFETs, which may be finFETs, that is arranged to drive a much smaller current than the current handled at the PD mode clamp. The ESD RC-MOS clamp may be formed of a RC circuit structure or branch and MOSFET circuit structure or branch (or MOSFET pass branch) where the RC branch may be an RC timer formed of two pairs of RCs, and each of the MOSFETs may have a gate coupled to a an RC pair. This arrangement permits the RC timer to divide discharge leakage voltage (or current) evenly (or other desired division) between the two MOSFETs for dissipation of the voltage (or current).

It has been found that the two stage higher and lower voltage clamp arrangement can reduce stand-by current leakage to about 5 nA or less, which is 180 times less than known finFET 3.3V power clamps and for a positive current discharge (or CDM zap or stress) of 6 Amps. The two stage higher and lower voltage clamps also may protect devices from a human body model (HBM) current zap of 0.7 Amps (1 KV). It will be understood that the clamps could be adjusted for other target current amounts.

Thus, the disclosed reduced leakage from the two stage arrangements are significantly lower than that of known clamps. In addition, no latch-up susceptibility occurs since the parasitic BJT can hold voltage above a supply voltage level. The two stage clamp arrangement also may be constructed with a footprint area reduction of up to 20% compared to known solutions by using the VDD/IO resistor on the IO or VDD power interconnect to substantially reduce the current leakage to be handled by the RC-MOS clamp.

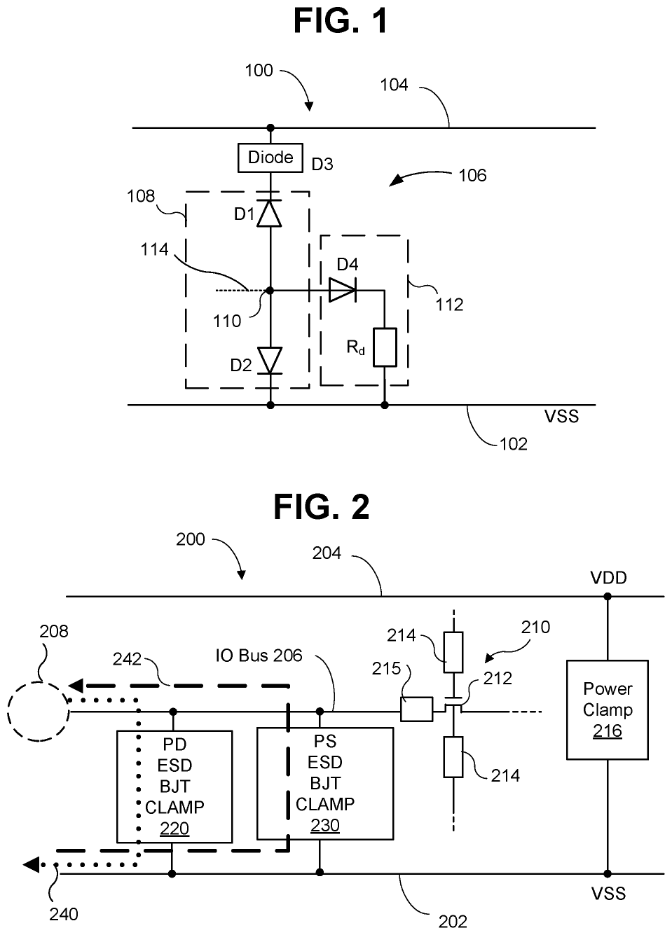

Referring now to FIG. 1 for one example approach, a device 100, such as an integrated circuit, comprises a first interconnect 102 that may be a conductive VSS line or rail and may be coupled to ground. The first interconnect 102 may provide a voltage. A second interconnect 104 may be an input-output (IO) signal bus line (or just IO bus) that provides a signal. The disclosed device 100 may have an ESD clamp 106 that has a parasitic bipolar junction transistor (BJT) circuit structure 108 with a metal-oxide semiconductor field effect transistor (MOSFET) first diode D1, and a MOSFET second diode D2 coupled in series with the first diode in an anti-parallel configuration. A first node 110 comprises a base of the BJT circuit structure 108 formed of the anodes of the first and second diodes D1 and D2. Thus, the first and second diodes D1 and D2 may be coupled to each other via the first node 110. The diodes D1 and D2 may be considered parasitic themselves since the diodes may be constructed from semiconductor well structures as described below. A third diode D3 may be coupled in series to the BJT circuit structure 108 and may have a forward bias directed away from or toward the BJT circuit structure 108 depending on the polarity or direction of the current (positive or negative) to be shunted (or in other words, depending on whether the ESD clamp 106 is a PD mode clamp or a PS mode clamp).

The first node 110 also is coupled to a base circuit structure 112 that has a fourth diode D4 in series with a deep n-well (or n-band) resistor Ra between the node 110 and the first interconnect 104 to soft tie the node or base 110 to the first interconnect 104, and regardless of the polarity of the current. A diode D4 may be coupled in series with the resistor Ra between the node 110 and the first interconnect 102. The resistor Ra may be coupled to an n-band or deep n-well of a triple well structure of the device 100. By some example forms, an optional base resistor (not shown) also may be provided for ballast at a coupling 114 and is coupled to the first node 110 with one end and coupled on another end to different terminals that depend on the polarity of the current and as described in greater detail below. This arrangement permits a greater amount of voltage to be shunted by the ESD clamp 106 so that at least +/−2.5 voltage swings can be handled while using and protecting smaller victim devices, such as devices with an operating voltage of 1.2V, for example.

Now referring to FIG. 2 for more details, an example device or circuitry 200 may be used to provide failsafe protection of “victim” HF TX circuits such as for communications, 5G mobile networks, and so forth for antennas, although other types of semiconductor devices may be protected in addition to, or instead of, the HF TX circuits. In this example, an interconnect 204 may be a VDD power, supply, or drive rail or line, while an interconnect 202 may be a VSS power rail that is coupled to ground and/or may provide a voltage. A third interconnect (or IO bus or IO interconnect) 206 may be an input-output IO bus or line that provides signals to and/or from one or more semiconductor devices 210 and may be coupled to a conductive feature 208, such as a pad, to receive the signals during normal use or run-time. A pad to VDD (PD) ESD BJT clamp 220 and/or a pad to VSS (PS) ESD BJT clamp 230 (also referred to as PD ESD clamp and PS ESD clamp, or just PD and PS clamps respectively) extends in parallel between the interconnect 206 and interconnect 202. The pad 208 also may be interconnected or coupled by circuitry (not shown) to the VSS interconnect 202 to close the circuit loops through the PD and PS clamps 220 and 230. This may or may not include using additional pads. The current polarity (or flow direction) is described herein relative to the pad 208 so that positive current (or negative voltage) 240 from the pad 208 and through the interconnect 206 may be permitted to flow through the PD ESD BJT clamp 220 and to the VSS interconnect 202, while negative current 242 may be permitted to flow from the VSS interconnect 202, through the PS clamp 230, through the IO interconnect 206, and to the pad 208. By one form, device 200 has both the PD and PS clamps 220 and 230 to shunt transient ESD no matter the direction or polarity of the transient ESD current between the interconnects 202 and 206. The current can be intentionally generated in the desired direction for testing by using a CDM or HBM to apply a negative zap or positive zap to the pad 208 to generate positive current or negative current, respectively.

The pad 208 may be any suitable conductive feature or connector such as contact or bond pad on integrated circuitry of device 200 and formed of conductive metal such as gold, copper, aluminum, other materials, or combinations thereof. The pad 208 may include, or be coupled to, one or more vias, pillars, traces, caps, landings, and so forth that may form components of a metallization layer or plane on an integrated circuit or semiconductor structure. The pad 208 may or may not be considered part of IO interconnect 206. The pad 208 may have sufficient surface area to provide adequate coupling to the interconnects and circuitry described herein and other circuitry to provide input and/or output of power and/or data. Otherwise, the pad 208 may be provided in any suitable shape, size, and arrangement.

The victim semiconductor devices(s) 210 to be protected may be HF TX metal oxide semiconductor (MOS) switches or circuits, but may be many different semiconductor devices or types of devices, or combinations of devices. By one form, the semiconductor devices 210 may be formed of N3 or N5 FinFETs, or N5 technology and smaller. By one alternative form, the semiconductor devices may include N6 technology or smaller, but otherwise is not limited in size or technology generation for semiconductor devices to be protected from at least some transient discharge by at least some amount with the clamps described herein. The protected semiconductor devices 210 can have many different architectures and circuitry. The semiconductor devices 210 may be directly connected to one or both power rails 202 and 204. Otherwise, the devices 210 may be coupled to other devices or circuitry that are in turn coupled to either or both of the power rails 202 and 204. By one example, the possible victim semiconductor device 210 may include a finFET switch 212 and optional ballasting resistors 214 and 215 at least at one of the gate, body and source of the finFET switch 212, or any combination thereof to provide soft coupling. By one form, only the source resistor 215 is used. By one example, the source resistor 215 may be a metal resistor with a resistance of about 1-10 Ohms and that is coupled to the IO interconnect 206, while the other two resistors 214 may be semiconductor ballasting resistors and may have a resistance of 10 kOhms. Many other variations of victim semiconductor device circuitry may be used.

Also, a power clamp 216 may extend from the VDD interconnect 202 to the VSS interconnect 202 to protect against transient discharge more directly on the VDD interconnect 204, and the architecture of such a power clamp 216 is not limited for this example.

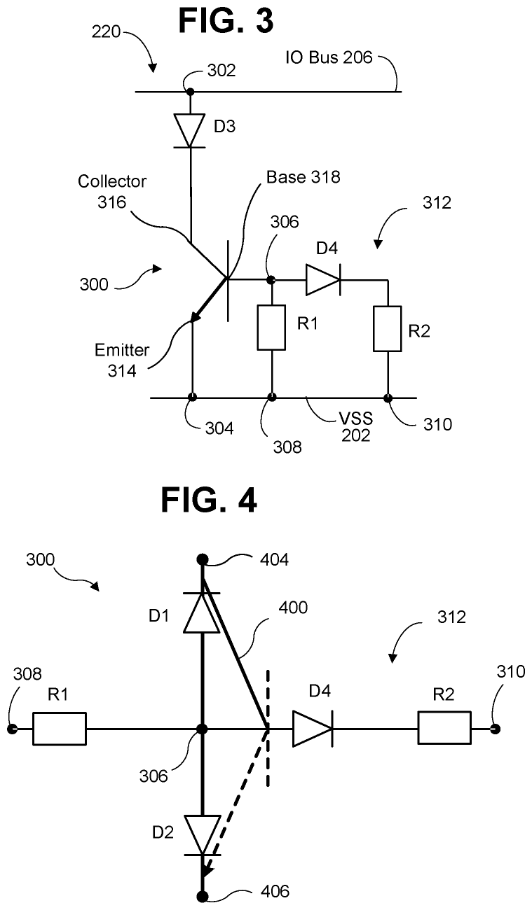

Referring to FIG. 3, the PD ESD clamp 220 may be coupled to the interconnects 206 and 202 respectively by terminals (or nodes) 302 and 304. The PD ESD clamp 220 may have a parasitic BJT circuit structure 300 with an emitter 314 coupled to the VSS interconnect 202, and a collector 316 coupled in series to a diode D3 which in turn is coupled to the IO interconnect 206. With this arrangement, the BJT circuit structure 300 is coupled in series with the diode D3. The diode D3 has its cathode coupled in series with the collector 316 while an anode of the diode D3 is coupled to the IO interconnect or bus 206. With this arrangement, the diode D3 is polarized for conduction of positive current received from the IO interconnect 206 and provides a forward bias of the positive current toward the BJT circuit structure 300 so that the PD clamp 220 can become low-ohmic and current may be permitted to flow through the PD clamp 220. Otherwise, the diode D3 is reverse biased and the PD clamp remains in a high-ohmic state to reduce negative current flow from the interconnect 202. The diode D3 may be a stacked diode with separate semiconductor well structure than that of the BJT circuit structure 300, and specifically stacked in series with wells of the BJT circuit structure 300 (as described below). With this arrangement then, the diode D3 reduces a capacitive load of the PD clamp 220.

The BJT circuit structure 300 also has a base 318 formed by a base node 306, and a base circuit structure 312 may be coupled to the BJT circuit structure 300 at the base node 306. An optional base resistor R1 may be coupled between the interconnect 202 at a terminal 308 and the base node 306. In addition, a deep n-well resistor R2 may be coupled between the interconnect 202 at a terminal 310 and the base node 306. The resistors R1 and R2 may be in parallel between the base node 306 and the interconnect 202. Also, a fourth diode D4 may be coupled in series to the resistor R2 and between the base node 306 and the interconnect 202.

Referring to FIG. 4, the parasitic BJT circuit structure 300 has anti-parallel or back-to-back diodes D1 and D2 and a BJT 400 shown superimposed over the anti-parallel diodes D1 and D2 to indicate the representation of the diodes D1 and D2 by the BJT 400. The BJT 400 may be an NPN BJT where diode D1 may be an n-type collector diode at the collector 316 with a collector terminal 404 to be coupled to diode D3, and diode D2 may be an n-type emitter diode at the emitter 314 with an emitter terminal 406 to be coupled to the interconnect 202. The emitter 314 and emitter terminal 406 may be referred to interchangeably, while the collector 316 and collector terminal 404 also may be referred to interchangeably.

The anodes of the anti-parallel diodes D1 and D2 may be coupled to each other via base node 306. In other words, the base node 306, and in turn base 318, of the parasitic BJT circuit structure 300, may be considered to be formed by the anodes of the anti-parallel diodes D1 and D2. Also, the diodes D1 and D2 are themselves parasitic. Thus, for the present example, the diodes D1 and D2 may be n-type diodes and may be, or represent, n-type doped, or n-diffusion, regions of a p-type well structure as described below, while the base is formed by a well region of p-type doping (or p-diffusion).

When positive current is applied to the BJT circuit structure 300, current will be present at the base node 306 and diode D3 opens, due to avalanche at the collector 316 and the base or base junction 318. The voltage drop at resistor R1 biases the base of BJT 300. Once junctions in the BJT 300 are forward biased, the BJT starts conducting current from collector (D1 node 404) to emitter (D2 node 406).

The transient current that reaches the VSS interconnect 202 through the BJT 400 then may be shunted to ground.

In reverse bias mode with negative current, the negative current cannot reach the base 306 or 318 in significant amounts due to the reverse biased diode D3, and therefore, the diodes D1 and D2 “bust” the BJT between both cathodes, or in other words, stop or significantly reduce the current flow from one anti-parallel diode to the other since diode D2 also will block negative current from passing through the BJT circuit structure 300.

By one form, the anti-parallel n-type diodes D1 and D2 may have a capacity, or be rated for, a 1.8V supply or operating voltage to be adaptable to protect devices with older and larger MOSFETs but also can be used to protect the more modern and smaller MOSFETS, such as with the N3 or N5 technology for example.

The deep n-well resistor R2 may be used to provide voltage bias and limit current in n-band. Specifically, an n-band connection of a triple well may be tied to the VSS interconnect 202 via the resistor R2. By one form, the resistor R2 may have a resistance of about 10 kOhms. The resistor R2 may be used to suppress or reduce built-up charge from unintended bipolar current during operation by being coupled to a guard-ring within the deep n-well as described below.

Also, the diode D4 in series with the deep n-well resistor R2 may be a parasitic or implicit diode formed by the guard-ring (described below). The guard ring may be n-type. A P-N junction of the diode D4 may be formed by an isolated p-well and adjacent n-well (here being the deep n-well or n-band). As mentioned, the diode D4 may isolate the base 306 or 318 under negative current ESD, and in reverse bias to stop or reduce the bipolar action between the diodes D1 and D2.

By one option, the base resister R1 may be provided to soft tie the base node 306 (and particularly a p-type region (that may be a p-tap) within an isolated p-well) to the interconnect (or ground or VSS) 202 in order to support BJT triggering and current conduction away from the IO interconnect 206 under ESD. By one form, the base resistor R1 may have a resistance of about 10 kOhms to attempt to limit the amount of current in the iso-p-well and to attempt to assist trigger of the parasitic BJT 300.

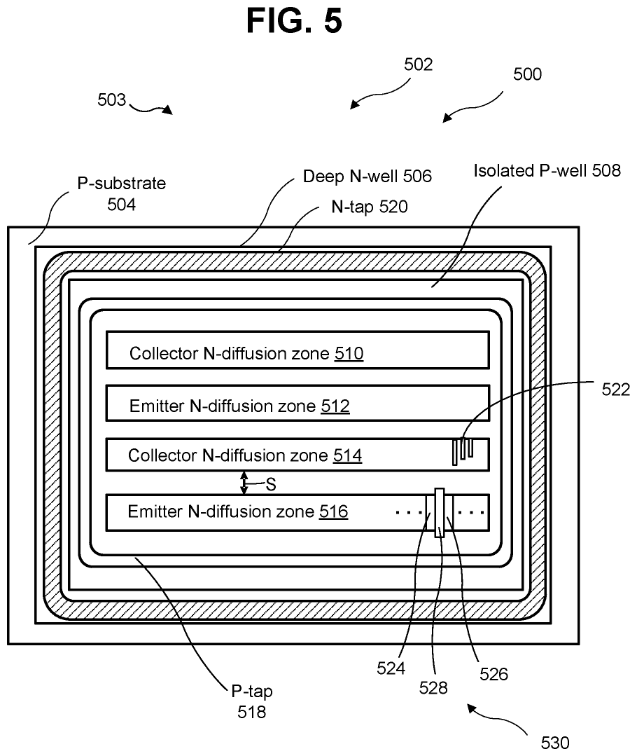

Referring to FIG. 5, an example semiconductor (or integrated circuit) structure 500 may have one or more PD ESD clamps 502 as described herein. Thus, multiple PD ESD clamps 502 may share a well structure 503. The example semiconductor structure 500 here has a triple well including a p-type substrate (or just p-substrate) 504 supporting a deep n-well (or n-band) 506, which in turn supports an isolated p-well 508. The isolated p-well 508 also has n-doped or n-diffusion zones or regions 510, 512, 514, and 516, here shaped in elongated strips, stripes, or bars, and may be formed by one or more finFETs 522. By one form, spacing S between each collector and emitter zone should be in range of minimum DRC spacing so that space between the emitter and collector of the BJT can be low-ohmic.

Each adjacent pair of collector and emitter zones 510 and 512, or 514 and 516, may be used to form a collector and emitter of a parasitic BJT of one or more, or many, PD ESD clamps. Each zone 510, 512, 514, and 516 may support multiple MOSFETs 530 extending transversely along the width of the zones 510, 512, 514, or 516. Each MOSFET 530 may have a source strip 524, a drain strip 526 and a floating gate 528 between the source 524 and drain 526. The strips may be placed in close proximity, such as minimum DRC apart or straddling.

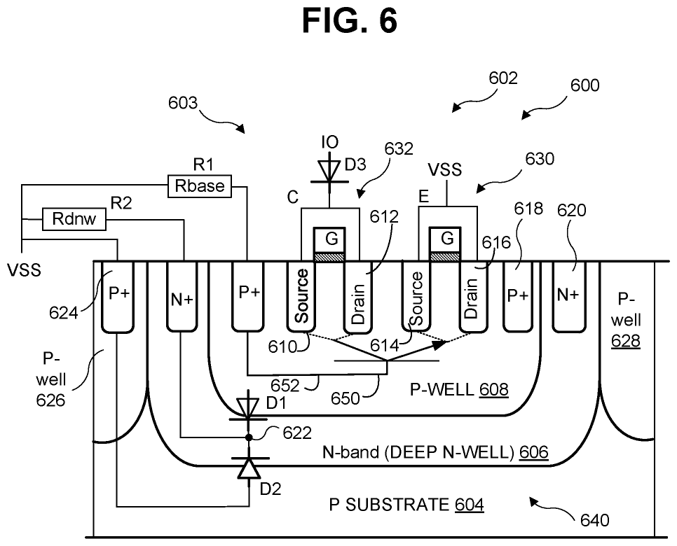

As mentioned, the anti-parallel diodes D1 or D2 forming the parasitic BJT circuit structure may themselves be parasitic and each diode D1 or D2 may represent one of the MOSFETs 530 as well as other PN junction structure described below on FIG. 6. Thus, the anti-parallel diodes may be referred to as MOSFET diodes. Each emitter zone 512 and 516 may have multiple emitter MOSFETs 530, and in turn emitter MOSFET diodes D2 spaced along the length of the emitter zone, while each collector zone 510 and 514 may have multiple collector MOSFETs 530, and in turn MOSFET diodes D1 spaced along the length of the collector zone. It will be appreciated than that each MOSFET may have a source or drain region 524 or 526 supported by one or multiple finFETs 522 forming a single zone 510, 512, 514, or 516. In other words, a single source or drain may cross over multiple fins. Other variations include separate drains along the same width line but each on a different fin within the same single emitter or collector zone.

In order to reduce undesired build up of charge, the semiconductor structure 500 also may have a p-type tap (or p-tap) 518 which is a p-type doped region shaped in a ring around the collector and emitter zones 510, 512, 514, and 516 and extending within isolated p-well 508. A guard ring or n-tap 520 (shown in hash line) is an n-type doped region extending in the deep n-well 506 and shaped in a ring around the isolated p-well 508.

Referring to FIG. 6, a semiconductor device or integrated circuit structure 600 has a well structure 602 for a PD ESD clamp 603 and with both an emitter E MSOFET 630 and a collector C MOSFET 632 shown here side by side in the same well for explanatory purposes and clarity although the two MOSFETs 630 and 632 actually may be one behind the other in separate collector and emitter zones as described in FIG. 5. Thus, the well structure 602 components with the same or similar labels are the same or similar structure to that on the top view of device 500 (FIG. 5). The well structure 602 here also is shown with merely two of the MOSFETs while such a well structure along one or more collector or emitter zones may have many more MOSFETs. Many different arrangements may be used as long as the emitter E MOSFET 630 and the collector C MOSFET 632 of the same PD ESD clamp are in the same well, and by one form, within the same triple well structure.

For the well structure 602, a p-type substrate (p-substrate) 604 may support a deep n-type well (or deep n-well or n-band) 606, which in turn has an isolated p-well 608 within the deep n-well 606, where the deep n-well (or n-band) extends under and on the exterior sides of the p-well, thereby forming an NPN triple well structure 640. Adjacent P-wells 626 and 628 may be adjacent the deep n-well 606. A parasitic BJT 650 represents the anti-parallel diodes D1 and D2 (from FIGS. 3-4), which in turn are parasitic diodes that each represent one of the MOSFETs 630 and 632 as well as PN junctions between the wells. Thus, for example, the collector diode D1 may represent the collector MOSFET 632 and the PN junction between the isolated p-well 608 and the deep n-well 606 as shown by the positioning of the diode D1 on the well structure 602. Likewise, the emitter diode D2 may represent the emitter MOSFET 630 and the PN junction between the deep n-well 606 and the p-substrate 604 as shown by the positioning of the diode D2 on the well structure 602. The diodes D1 and D2 are oriented to show the charge polarity of their anodes and cathodes even though the diodes D1 and D2 are oriented as anti-parallel, or back-to-back, diodes as shown on FIGS. 3-4. Thus, the PN junctions act as back-to-back diodes D1 and D2 placed in the same iso-p-well 508 (or base of BJT).

The collector MOSFET 632 has a source region 610, a drain region 612, and a floating gate G between the two regions 610 and 612 and over a dielectric layer that may be a gate oxide layer, and so forth. The emitter MOSFET 630 has a similar structure with a source region 614, a drain region 616, and a floating gate G between the two regions 614 and 616.

The source 614 and drain 616 of the emitter MOSFET 630 are coupled to the VSS interconnect, while the source 610 and drain 612 of the collector MOSFET 632 are coupled to the diode D3 to receive positive transient current when present. The diode D3 is coupled to the IO interconnect or bus as explained above. A p-tap 618 formed in a p-doped region in the isolated p-well 608 may extend around the source and drain regions (as shown in top view in FIG. 5), and a base 652 of the of the BJT 650 may be coupled via the non-doped (or differently doped) area of the isolated p-well 608 to the p-tap 618. When present, a base resistor (Rbase or R1) may be coupled between the p-tap 618 and the VSS interconnect.

A guard rail or n-tap 620 formed of an n-doped region of the deep n-well 606 may extend around the isolated p-well 608 The base of the BJT 650 also may represent a base node 622 interconnecting the diodes D1 and D2 within the deep n-well 606. The base node 622 is coupled to the guard ring 620, and the guard ring may be coupled to a deep n-well resistor R2, which in turn is coupled to the VSS interconnect thereby soft tying the deep n-well to VSS. An implicit diode (thus, not shown) and representing diode D4 on FIGS. 3-4 may be considered to be in series with the resistor R2 and represents the PN junction between the isolated p-well and deep n-well in addition to the anti-parallel diode D1.

The adjacent p-well 626 also may have a p-tap or p-doped region 624. The emitter diode D2 may be coupled to the VSS interconnect via the p-tap 624 in addition to the coupling of the emitter source and drain regions 614 and 616 to VSS interconnect.

In operation, a positive current may flow through the open diode D3 to reach the collector source and drain regions 610 and 612 so that the positive voltage appears at the collector diffusions 610 and 612 of the BJT (formed from a n-channel (nch) with a floating gate). While ramping the voltage at D3, the reverse bias of junction nch to iso-p-well increases until avalanche current starts flowing to base 652 and parasitic BJT fires which results in forward bias current in the base 652 of the BJT 650. Note that resistor R1 causes an extra voltage drop in the base 652 during breakdown current flow in the base. Once the parasitic BJT is fired, it changes the state to low-ohmic and can shunt the ESD current from IO via D3 to emitter 630 at VSS.

The wells 606 and 608 are formed on finFETs with the source and drain regions extending along the length of the fins as described above with FIG. 5. The substrate 504 or 604, the deep n-well, and isolated p-well may be formed of silicon, single-crystalline silicon, alloys thereof, compound semiconductor alloys such as SiGe, GaN, InP, InSb, InAS, and/or other III-N or III_V materials, to name a few examples. The dopants may be formed of Phosphorus for the n-regions (e.g., n-well) and Boron for the p-regions (e.g., p-well). The construction and doping of the wells and finFETs mentioned herein may be performed by known methods.

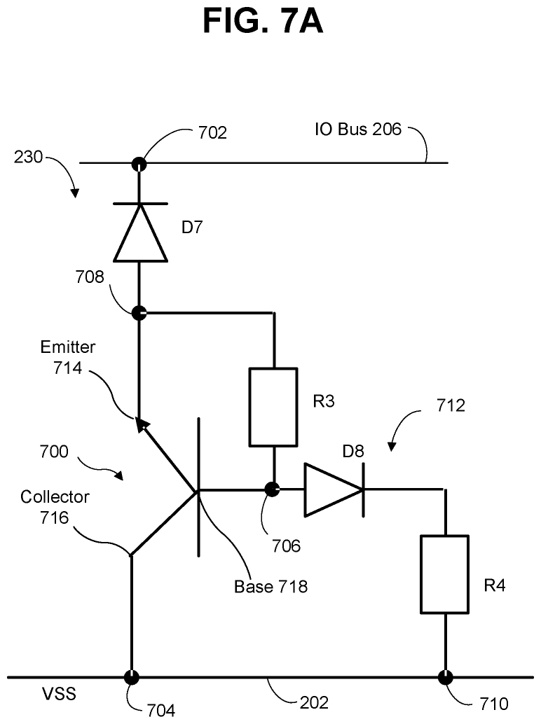

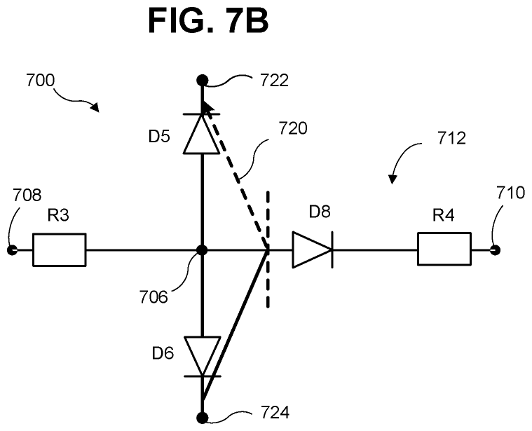

Referring now to FIG. 7A, much of the description of the example PS clamp 230 is the same or similar to the example PD clamp 220 already described above, and components of the PS clamp 230 shown on FIGS. 7A-7B are numbered similarly to that of FIGS. 3-4. Here, however, a parasitic BJT circuit structure 700 has an emitter 714 coupled in series to an n-type diode D7 and a collector 716 coupled to the interconnect 202. The diode D7 has a cathode coupled to the IO interconnect or bus 206 and an anode coupled in series to the emitter 714. The diode D7 may have its own separate well structure, which may be a triple well structure, stacked with the triple well of the PS clamp's BJT circuit structure 700. When positive current is received from the IO interconnect 206, the diode D7 is in reverse bias and blocks most or all of the current so that the PS clamp 230 remains high-ohmic. Otherwise, when negative current is received from the VSS interconnect 202, the diode D7 is in a forward bias mode to permit the current to flow from the PS clamp 230 and to the IO interconnect 206, and by one form to pad 208.

Also, when an optional base resistor R3 is provided, the base resistor R3 may be coupled between a base node 706 and the emitter 714 rather than to the interconnect 202. This may be provided to maintain the p-well at a lower or lowest potential under ESD. The resistor R3 may have a node or terminal 708 coupled between the emitter 714 and diode D7. The base resistor R3 may have a resistance of about 10 kOhms by one example.

Referring to FIG. 7B, the BJT circuit structure 700 has anti-parallel or back-to-back diodes including an emitter diode D5 and a collector diode D6 of parasitic BJT 720. In this case, negative current flows from the collector terminal 724 and to the emitter terminal 722, and towards the IO interconnect via diode D7 (FIG. 7A). Otherwise, the anti-parallel diodes D5 and D6 operate the same as anti-parallel diodes D1 and D2 except for the change in emitter and collector positions. Also in this case, node 708 couples resistor R3 to the emitter as explained on FIG. 7A rather than to the VSS interconnect 202. The base circuit 712 is arranged similar to base circuit 312, and operates in the same manner such that deep n-well resistor R4 is similar to resistor R2, and diode D8 is similar to diode D4.

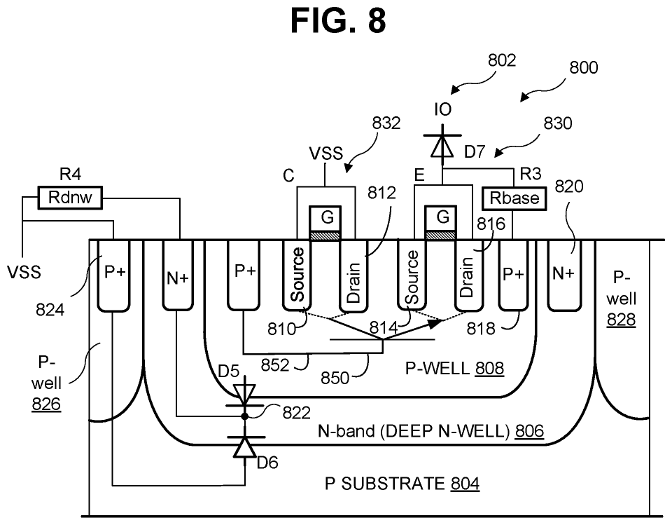

Referring to FIG. 8, and with regard to the semiconductor well structure of the PS clamp 230, the top view is the same or similar to that of FIG. 5 and no further explanation is needed. As to the stacked and other circuit connections to the wells, a semiconductor device structure 800 may have well structure 802 that is similar to that of well structure 602 (FIG. 6) such that all of the details of the wells need not be repeated here. Thus, the descriptions of the structures here numbered similarly to that of FIG. 6 also do not need to be repeated here. The well structure 802, here however, has source and drain regions 810 and 812 of a collector C MOSFET 832 coupled to VSS (or VSS interconnect or ground). Source and drain regions 814 and 816 of an emitter E MOSFET 830 are coupled to the stacked diode D5, which in turn is coupled to the IO interconnect. The base resistor R3 may be coupled to the p-tap 818 and to the emitter MOSFET 830.

This arrangement permits negative current to flow from the collector 832 to the emitter 830 when charge is at the base 822 at the deep n-well 806. The n-well 806 is tied via resistor R4 to prevent substantial current flow in unintended parasitic BJT formed by D5 and D6. The p-well 808 is attached to R3 provide voltage bias under current flow and to permit current to flow through the parasitic diode D6, and through the BJT structure 700 or here 850 with base 852.

Stand-alone versions of the disclosed PD and PS ESD clamps were tested using CDM. Both clamps received both a positive current (negative voltage zap) and a negative current (positive voltage zap) to test both the opening and closing of the PS and PD ESD clamps. The PS and PD clamps were tested using N5 hardware technology and were dimensioned to sustain a 4 A CDM current with a permissible capacitive load of approximately 100 femtofarads (fF). The maximum current that can be handled by the PD and PS ESD clamps mostly depend on metallization and junction capacitance.

The clamps were tested to determine very-fast transmission line pulse (vfTLP) measurements in both the forward and reverse current directions as mentioned. TLP measurement was conducted for a TX node versus VSS in a positive current direction for the PD clamp and a negative current direction for the PS clamp for the intended conduction of ESD current through the clamps. TLP measurement was also conducted for a negative current direction for the PD clamp and a positive current direction for the PS clamp when the clamps should remain closed or high-ohmic.

It was found that in the forward direction for the PD clamp, vfTLP voltage was at most 6V at 4 A, whereas in the reverse direction, damage occurred at approximately −8 to −9V TLP. Similarly, in the forward direction for the PS clamp, the vfTLP voltage was at or greater than −7V at 4 A, whereas in the reverse direction, damage occurred at about 9V TLP. These clamping voltages are sufficient for victim TX switches with ballasting resistors. The trigger voltages provide a sufficient window for signals in operation for +/−2.5V and even up to a voltage swing of +/−3V.

The leakage through the stacked diode in forward direction provides a voltage drop and reduces the overvoltage at the parasitic BJT. Thus, DC leakage measurements of the stand-alone versions of the disclosed PD and PS ESD clamps also were performed for the full sweep of +/−2.5V at room temperature (RT). The leakage measurements for both the PD and PS ESD clamps were found to be at most 10 nA at RT. The leakage mostly originates from reverse bias at the PN junctions of the stacked diodes in series with the parasitic BJTs and/or the anti-parallel diodes of the parasitic BJTs.

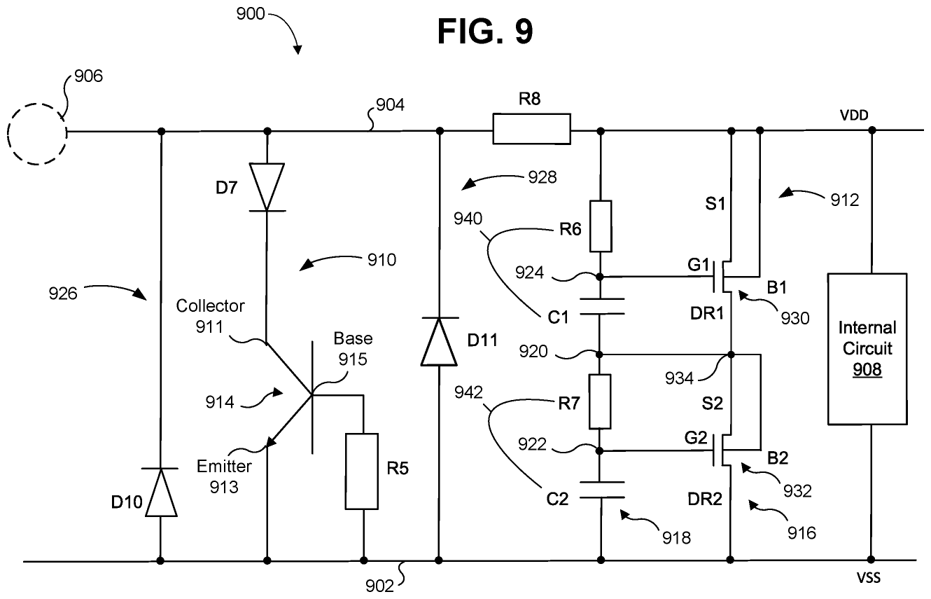

Referring to FIG. 9, an alternative ESD protection circuit implementation has a semiconductor or integrated circuit device 900 for ultra-low current leakage. By one alternative, this example may be used with a VDD supply line of real time clock circuit such as those provided on a mother board although many other circuits with timers may be used. The circuit also can be used as an ESD protection of an IO data pin.

The semiconductor device 900 may have a VDD interconnect 904 that may be a power, supply, or drive rail or line. The device 900 also may have a VSS interconnect 902 that may be a power rail that is coupled to ground and/or may provide a voltage. The VDD interconnect 904 may be coupled to a conductive feature or connector 906 such as a pad, bump, cap, and so forth as described above with pad 208. The pad 906 may be coupled to the VSS 902 by circuitry not shown to close an electrical loop circuit with the ESD clamps. Transient positive or negative current ESD may be applied to the pad 906 that is to be shunted by the ESD clamps.

One or more internal circuits 908 with one or more victim semiconductor devices to be protected may be coupled to the two rails 902 and 904. The semiconductor devices of the internal circuits 908 may having operating voltage of 3.3V by one example, but otherwise is not limited in structure or the type of devices for the ESD protection. Here in this example, the VDD interconnect 904 may have target operating input and output at 3.3V to operate the devices or circuits 908.

The semiconductor device 900 provides two stage ESD protection with a higher voltage ESD clamp 910 used in a first stage and a lower voltage ESD clamp 912 that shunts current leaked by the higher voltage ESD clamp during an ESD event and in a second stage. Both ESD clamps extend in parallel between the interconnects 902 and 904. By one approach, the higher voltage ESD clamp 910 may have a first voltage trigger level that is higher than a second voltage trigger level of the lower ESD clamp 910. By one form, the higher voltage ESD clamp 910 has the first trigger voltage level over 4V, and by one form up to 6.5V, while the lower voltage ESD clamp 912 has a second trigger voltage level that is less than 4V and may be smaller. By one example, the second trigger voltage level is zero, or in other words, any non-zero voltage slew rate within the specification for ESD will activate (or in other words open or permit current to flow) the lower voltage ESD clamp 912.

The triggers also can be put in terms of current. Thus, the higher voltage ESD clamp 910 may be a higher current ESD clamp, and by one example with a target trigger current of at least 6 A. In this case, the lower voltage ESD clamp 912 is a lower current ESD clamp, and may have a trigger current of at 1.0 A to 1.5 A, or at most 1.5 A by one example.

By one form, the higher voltage level clamp 910 and the lower voltage level clamp 912 both shunt positive transient current (negative voltage or negative CDM zap) applied to the pad 906. Thus, the clamp 910 may be a PD ESD clamp. The clamp 912 is an RC-MOS clamp, which may be a power clamp, to shunt and reduce positive current leakage from the PD ESD clamp.

The PD ESD clamp 910 is similar to the ESD PD clamp 220 with a parasitic NPN BJT 914, except here without a deep n-well base circuit. The parasitic BJT circuit structure 914 may have an emitter 913 coupled to the VSS interconnect 902 and a collector 911 coupled in series to a cathode of a diode D7. The diode D7 has its anode coupled to the VDD interconnect 904. By one example, the diode D7 may be a p-type diode within an n-well separate from dual wells of the BJT circuit structure 914, although both may be stacked together in the same semiconductor device. So arranged, the diode D7 opens in a forward bias for positive current to flow to the BJT circuit structure 914, and closes in reverse bias to stop or reduce negative current from the VSS interconnect 902. The BJT circuit structure 914 may be rated below 3.3V supply while the VDD provides 3.3V due to reliability reasons such as junction degradation over the lifetime of the device. However, this reliability issue is solved by using the diode D7 in series, which improves current leakage further.

A 10 kOhm base resistor R5 is coupled to the BJT circuit structure 914 to provide a soft tied ballasted coupling of the base 915 to the VSS interconnect 902 and in parallel to the coupling from the emitter 913 to the VSS interconnect 902.

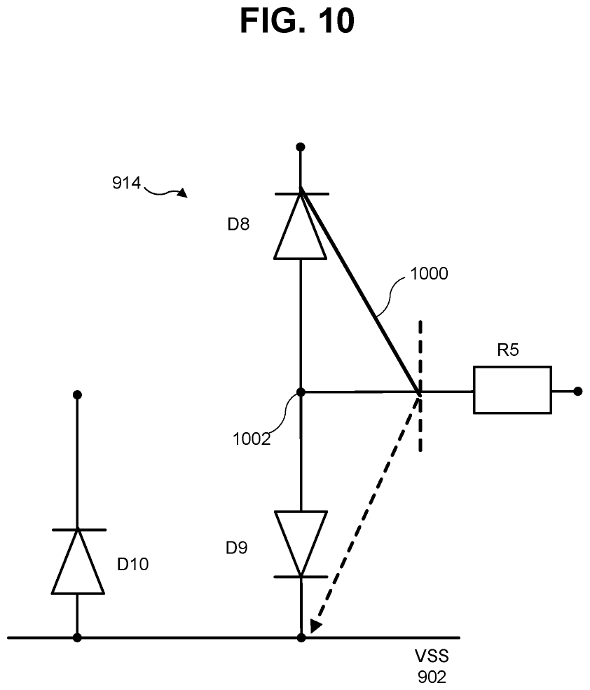

Referring to FIG. 10, the parasitic BJT circuit structure 914 has a parasitic BJT 1000 with back-to-back or anti-parallel diodes including a collector diode D8 and an emitter diode D9 as explained above with diodes D1 and D2. The diodes may be n-type diodes coupled to each other via a base node 1002 representing base 915 and which also may be coupled to the base resistor R5 and in turn to VSS interconnect 902. As described above with diodes D1 and D2, here too the diodes D8 and D9 may have p-type anodes considered to form the base 915 or base node 1002. By one form, the diodes D8 and D9 are parasitic with each diode representing a MOSFET with source and drain regions and a floating gate as described with diodes D1 and D2 above. The source and drain regions may be strips extending along a width of fins of finFETs also as explained above with FIG. 5.

The well structure of the BJT circuit structure 914, however, may use a dual well structure rather than the deep n-well in a triple well. Thus, the source and drain regions may extend within a p-well that is directly supported by a p-type substrate. In this case, the parasitic diodes D8 and D9 also represent the PN junctions between the p-well and the substrate. Alternatively, the well structure can be the same or similar to that shown in FIGS. 5-6 with a deep n-well when desired. In one example implementation, the BJT circuit structure 914 optionally may be formed in a dual-well process and may be decoupled from global ground by an n-well guard-ring placed around the BJT circuit structure and connected to the VDD interconnect 3.3V input. The guard ring is described in greater detail below.

Referring again to FIG. 9, the RC-MOS clamp 912 is formed of a double MOSFET (or MOS) circuit structure or branch 916 that actually performs the clamping, and a resistor-capacitor (RC) timer circuit structure or branch (or just RC timer) 918 that controls the MOS circuit structure 916. The RC timer 918 has two RC pairs coupled in series with each other at a timer node 920 and including an RC pair 940 coupled to the VDD interconnect 904, while a second RC pair 942 is coupled to the VSS interconnect 902. Each RC pair includes a resistor coupled to a capacitor. In this example, the first RC pair 940 has a resistor R6 and a capacitor C1 coupled to each other via a common node 924. The second RC pair 942 has a resistor R7 coupled to a capacitor C2 via a common node 922. In this example, the resistor R6 is coupled between the common node 924 and the VDD interconnect 904, the timer node 920 is coupled between the capacitor C1 and the resistor R7, and the capacitor C2 is coupled between the common node 922 and the VSS interconnect 902. It will be understood that other combinations and orders of the RC pairs in the RC timer 918 also will be adequate. In this example, the resistors R6 and R7 may have resistances of 100 kOhm each, and the capacitors C1 and C2 may have capacitive loads of 2 pF each, although other variations could be used.

As mentioned, the RC timer 918 may control the MOS circuit structure 916. The MOS circuit structure 916 may have two MOSFETs 930 and 932 that may be P-type MOSFETs (PMOS) or complementary MOSFETs (CMOS). Of these, a MOSFET 930 has a source S1 coupled to the VDD interconnect 904, and a gate G1 coupled to the common node 924 between the resistor R6 and capacitor C1 of the RC pair 940. The MOSFET 930 also may have a body (or bulk) B1 coupled to the VDD interconnect 904 in parallel to the source S1, and a drain DR1 that is coupled to the source S2 of the MOSFET 932 at a bridge bias node 934 in a shared-diffusion layout style thereby coupling the MOSFETs 930 and 932 to each other in series. The MOSFET 932 also has a gate G2 coupled to the common node 922 between the resistor R7 and capacitor C2 of the RC pair 942. Thus, MOSFET 932 also has a drain DR2 coupled to the VSS interconnect 902 and a body (or bulk) B2 coupled back to its own source S2 at the bridge bias node 934, which significantly reduces the stand-by leakage current because when the gate G2 is in an open state, the leakage is minimized through the transistor DR2. The node 924 is coupled to the timer node 920 so that the node 924 also remains open with minimized leakage through the transistor DR1.

Each MOSFET 930 and 932 may be formed or stacked in separate wells from each other thereby forming a stacked pass-device. By one example form, each MOSFET may be arranged to conduct 300 mA of transient ESD current (tested by using CDM negative zap or positive current), or 100 mA of transient ESD current (tested by using HBM positive zap). By one form as mentioned, and with specification of the components mentioned above, the RC-MOS clamp 912 may have a 0.1 A to 1.5 A, or at most 1.5 A, trigger current or ESD stress to activate the RC timer and to be shunted or dissipated.

As mentioned, a resistor R8 may be placed on the VDD interconnect 904 between the PD ESD clamp 910 and the RC-MOS clamp 912 to reduce the amount of leakage current flow reaching the second stage RC-MOS clamp 912 from the VDD interconnect 904 and in turn, the victim devices. By one form, the resistor R8 has a resistance of about or exactly 10 Ohms, but can be a different resistance amount depending on the victim semiconductor devices (or internal circuit) 908 and applications being used. During ESD stress, the resistor R8 also reduces clamping voltage that can reach the victims due to the R8 resistor's own IR drop so that voltage appearing at a bump during ESD is reduced by an IR drop over R8 at the victim (or in other words, the functional circuitry creating the victim).

The use of the resistor R8 can enable a reduction of up to 20% in integrated circuit area or footprint compared to known ESD clamp devices and depending on the ballast resistance value of resistor R8. The resistor R8 may be a metal resistor coupled to separate wells forming the PD clamp 910 and/or RC-MOS clamp 912. Resistor R8 may be a poly resistor or n-well resistor. By one example form, the potential U across the resistor is U=300 mA×10 Ohm=3V.

In operation, when positive current is applied to the pad 906 and generates current and/or voltage along the VDD interconnect 904 with current and voltage over the first thresholds of the PD clamp 910, the diode D7 then opens and the BJT circuit structure 914 directs the current to the VSS interconnect 902 through both the emitter and the ballast base resistor R5 when sufficient charge is present at the base 915 or 1002.

Remaining transient ESD current at the VDD interconnect 904 then has its leakage current reduced at the resistor R8 to levels that can be handled by the RC-MOS clamp 912. For example, if a trigger current level is met by transient ESD current at 6 A, the PD clamp 910 may shunt 5.7 A of the total 6 A, with 0.3 A remaining as input at the resistor R8. The resistor R8 then may further reduce the 300 mA current to be handled by the RC-MOS clamp 912. The RC-MOS clamp 912 uses the RC pairs 940 and 942 to alternate which MOSFET 930 or 932 will transmit the transient ESD current flow to the VSS interconnect 902 or ground. In other words, the capacitive load and resistance of the RC pairs 940 and 942 are set according to an RC constant to control the current flow to gates G1 and G2 to open and close the MOSFETS 930 and 932 in an alternating manner. By one form, the RC constant is about, or exactly, 200 ns.

When gate G1 and G2 are activated at MOSFETs 930 and 932, transient current flows from source S1 to drain DR1, and then to the source S2 and drain DR2. The gate G1 is activated by timer RC pair 940 (R6 and C1). The gate G2 is activated by timer RC pair 942 (R7 and C2). As mentioned, the timer 918 may have a time constant in a range of an HBM pulse, and by one form of 200 ns. After triggering of the timer 918, the gates G1 and G2 remain open for a duration defined by the RCs of the timer 918. That implies that the timer 918 is sensitive to slew-rates less than 200 ns, and the timer 918 is an optimizer to open G1 and G2 for voltage slew-rates occurring during ESD events, which are say between 20 ps-10 ns. After a time set by the RC timer 918, the gates G1 and G2 are closed, and the MOS circuit structure 916 on clamp 912 switches to a high-ohmic state. In an off state, only leakage of the off state of the MOSFET 930 stacked with MOSFET 932 is drowned by the clamp stage.

A bridge bias node 934 is connected to the timer 918 in order to bias the timer node 920 to half of the potential appearing between VDD and VSS. In one example operation, the bridge node 934 is set to VDD/2 in result of leakage flow through transistors or MOSFETs 930 and 932. The timer 918 ensures minimal leakage through transistors or MOSFETs 930 and 932 if the timer node 920 is biased to VDD/2. In alternatives, the transistors or MOSFETs 930 and 932 can be set to the same or different size in order to tune the voltage at timer node 920 to VDD/2.

For negative current ESD protection, the semiconductor structure 900 may have at least one PS clamp. Here two PS clamps 926 and 928 are indicated on each side of the PD clamp 910. One of the diodes can be preferably an explicit n+/p-well ESD diode, and the other diode can indicate a parasitic diode between n-wells guard-ring at VDD around of the BJT 914 and p-bulk at VSS. By one approach, each of the PS clamps 926 and 928 have a single diode D10 and D11, respectively. With a cathode coupled to the VDD interconnect 904 and an anode coupled to the VSS interconnect 902. The result is to block positive current from the VDD interconnect 904 to the VSS interconnect 902 in a reverse bias, while permitting negative current from the VSS interconnect 902 to the VDD interconnect 904 in a forward bias. By one approach, one or more of the diodes D10 and D11 may be parasitic (or implicit) and may represent or form a PN junction between an n-well and a p-well and may have an n-doped region within the n-well to form an n-well guard-ring. The n-well guard interrupts the p-well. The diode, and in turn the guard ring, may isolate the BJTs base from the emitter and collector to “bust” (or stop or reduce) the bipolar action under ESD. By another alternative, one or more of the diodes D10 and D11 may be explicit diodes. By one form, the PS clamp 926 has an implicit diode D10, while the PS clamp 928 has an explicit diode D11. Other variations may be used instead.

More or less of the PS clamps may be used depending on a specification of ESD current targets. By one form, the PS clamps 926 and 928, and the PD clamp 910 are between the pad 906 and resistor R8, while the RC-MOS clamp is on the opposite side of the resistor R8 than the PD and PS clamps.

TLP analysis showed that although typical stand-by current leakage transient ESD for such a PD ESD clamp can be as high as 9 μA (9×10⁻⁷ A), the two stage clamps disclosed herein can reduce the stand-by current leakage to about 5 nA (5×10⁻⁹ A) or less, which is a reduction of at least 180 times.

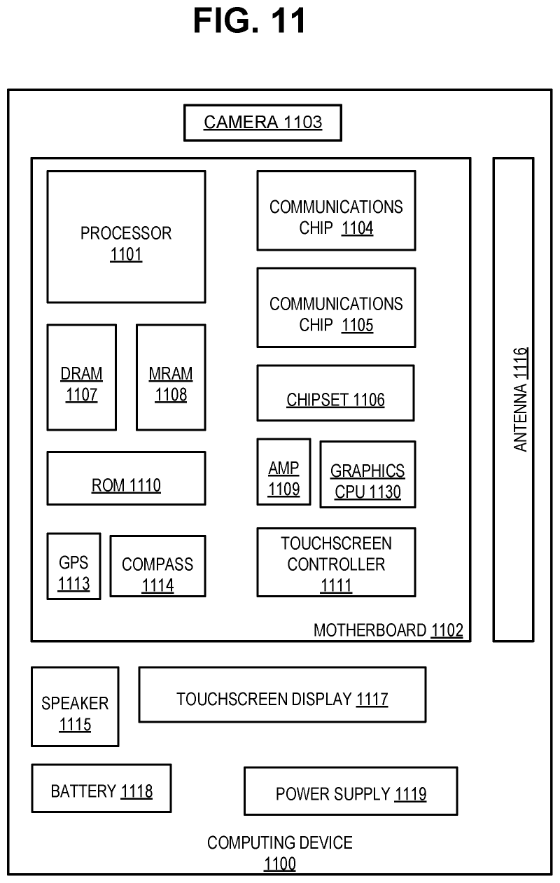

Referring to FIG. 11, a computing device or system 1100 is in accordance with implementations of the present disclosure. As shown, computing device 1100 houses a motherboard 1102. Motherboard 1102 may include a number of components, including but not limited to a processor 1101 and at least one communications chip 1104 and/or 1105. Processor 1101 is physically and electrically coupled to the motherboard 1102. In some implementations, communications chip 1105 is also physically and electrically coupled to motherboard 1102. In further implementations, communications chip 1105 is part of processor 1101.

Depending on its applications, computing device 1100 may include other components that may or may not be physically and electrically coupled to motherboard 1102. These other components include, but are not limited to, a chipset 1106, volatile memory (e.g., dynamic random access memory (DRAM)) 1107, magnetoresistive random access memory (MRAM) 1108, and/or other non-volatile memory (e.g., read only memory (ROM)) 1110, flash memory, a graphics processor, a digital signal processor, a crypto processor, an antenna 1116, a display, a touchscreen display 1117, a touchscreen controller 1111, a battery 1118, a power supply 1119, an audio codec, a video codec, a power amplifier 1109, a global positioning system (GPS) device 1113, a compass 1114, an accelerometer, a gyroscope, a speaker 1115, a camera 1103, a graphics CPU 1130, and a mass storage device (such as hard disk drive, compact disk (CD), digital versatile disk (DVD), and so forth).

Communications chip 1105 enables wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although that could occur in some implementations. Communications chip 1105 may implement any of a number of wireless standards or protocols, including but not limited to Wi-Fi (IEEE 1101.11 family), WiMAX (IEEE 1101.11 family), long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 11 G, and beyond. Computing device 1100 may include a plurality of communications chips 1104 and 1105. For instance, a first communications chip 1105 may be dedicated to shorter range wireless communications such as Wi-Fi and Bluetooth and a second communications chip 1104 may be dedicated to longer range wireless communications such as GPS, EDGE, GPRS, CDMA, WiMAX, LTE, Ev-DO, and others.

Processor 1101 of the computing device 1100, and/or other processing components of device 1100, includes an integrated circuit die. In some implementations, the integrated circuit die includes non-volatile memory devices, and one or more semiconductor structures that provide all or portions of any of circuits or devices 100, 200, 220, 230, 300, 700, and 900, 914, and/or semiconductor structures 500, 600, and 800 that include an ESD protection circuit with ESD clamps with BJTs alone or with one or more RC-MOS circuits, as described in association with any of FIGS. 1-10. The term “processor” used here may refer to any device or portion of a device with processor circuitry and that processes electronic data from registers and/or memory to transform that electronic data into other electronic data that may be stored in registers and/or memory.

Communications chip 1105 also may include an integrated circuit die packaged within communication chip 1105. In another implementation, the integrated circuit die of communications chips 1104, 1105 may include one or more interconnect structures, non-volatile memory devices, and/or capacitors. Depending on its applications, computing device 1100 may include other components of device 1100 that may or may not be physically and electrically coupled to motherboard 1102. In further implementations, any component housed within a housing or body of computing device 1100 and discussed above may contain a stand-alone integrated circuit memory die that includes one or more arrays of nonvolatile memory devices.

In various implementations, the computing device 1100 may be a laptop, a netbook, a notebook, an Ultrabook, a smartphone, a tablet, a personal digital assistant (PDA), an ultra-mobile PC, a mobile phone, a desktop computer, a server, a printer, a scanner, a monitor, a set-top box, an entertainment control unit, a game console, a digital camera, a portable music player, or a digital video recorder. In further implementations, the computing device 1100 may be any other electronic device that processes data.

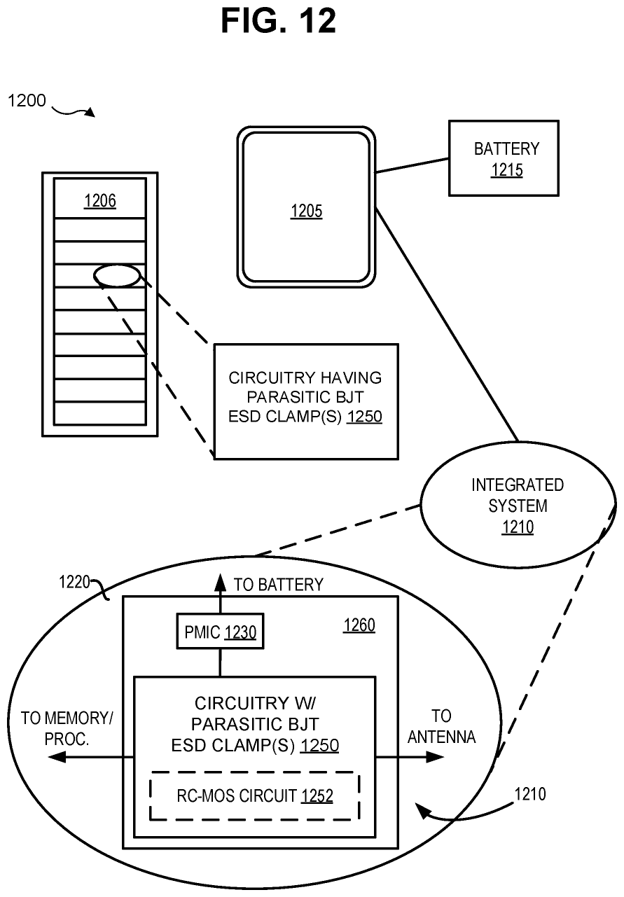

Referring to FIG. 12, a system 1200 has a mobile computing platform 1205 and/or a data server machine 1206 that employs circuitry including at least one parasitic BJT ESD clamp 1250, and optionally with at least one RC-MOS circuit 1252, for example in accordance with some implementations described elsewhere herein. Specifically, The server machine 1206 may be any commercial server, for example including any number of high-performance computing platforms disposed within a rack and networked together for electronic data processing, which in the exemplary implementation includes the circuitry 1250. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), a chip-level or package-level integrated system 1210, and a battery 1215.

Whether disposed within the integrated system 1210 illustrated in the expanded view 1220, or as a stand-alone discrete or packaged multi-chip module within the server machine 1206, the circuit 1250 includes at least one embedded or integrated parasitic BJT ESD clamp (whether PS or PD ESD clamps), and with or without one or more of the RC-MOS circuit clamps 1252, for example in accordance with some implementations described elsewhere herein. Circuitry 1250 may be further attached to a board, a substrate, or an interposer 1260 along with a power management integrated circuit (PMIC). Functionally, PMIC 1230 may perform battery power regulation, DC-to-DC conversion, etc., and so has an input coupled to battery 1215 and with an output providing a current supply to other functional modules.

Circuitry 1250, in some implementations, includes RF (wireless) integrated circuitry (RFIC) further including a wideband RF (wireless) transmitter and/or receiver (TX/RX including a digital baseband and an analog front end module comprising a power amplifier on a transmit path and a low noise amplifier on a receive path). The RFIC includes at least one embedded or integrated ESD diode, for example in an over-voltage protection circuit as describe elsewhere herein. The RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

It will be recognized that the disclosed features are not limited to the implementations so described, but can be practiced with modification and alteration without departing from the scope of the appended claims. For example the above implementations may include specific combinations of features as further provided below.

The following examples pertain to further implementations. Specifics in the examples may be used anywhere in one or more implementations.

In example 1, a device comprises a first interconnect to provide a voltage; a second interconnect; a parasitic bipolar junction transistor (BJT) circuit structure comprising a metal-oxide semiconductor field effect transistor (MOSFET) first diode and a MOSFET second diode coupled in series with the first diode in an anti-parallel configuration relative to each other, and a first node, wherein the first diode and the second diode are coupled to each other via the first node, and wherein the first node provides a base terminal of the parasitic BJT circuit structure; a third diode coupled between the second interconnect and the parasitic BJT circuit structure; and a first resistor coupled between the first node and the first interconnect.

In example 2, the subject matter of example 1, wherein the parasitic BJT circuit structure comprises: a first well structure of a first dopant type, wherein the first diode comprises first source or drain regions of a second dopant type and each extending at least partially into the first well structure, and wherein the second diode comprises second source or drain regions extending at least partially into the first well structure, and wherein the second source or drain regions are each of the second dopant type; and a first tap structure extending at least partially into the first well structure, around the first source or drain regions, and around the second source or drain regions, wherein the first tap structure is of the first dopant type.

In example 3, the subject matter of example 2, wherein the parasitic BJT circuit structure comprises: a second well structure extending under and around the first well structure, and having the second dopant type; and a second tap structure extending at least partially into the second well structure and having the second dopant type, wherein the second tap structure extends around the first well structure.

In example 4, the subject matter of example 2 or 3, comprising at least one fin structure of at least one fin field effect transistor (finFET) comprising at least one fin having either (1) the first source or drain regions or (2) the second source or drain regions.

In example 5, the subject matter of any one of examples 1 to 4, wherein the second interconnect is to communicate a signal, wherein the parasitic BJT circuit structure comprises a collector terminal and an emitter terminal, wherein the third diode comprises a p-type diode coupled to the collector terminal, and wherein the first interconnect is coupled to the emitter terminal.

In example 6, the subject matter of example 5, comprising: an input-output clamp circuit coupled between the first interconnect and the second interconnect; a fourth diode coupled in series with the first resistor between the first node and the first interconnect; and a second resistor coupled, in parallel with the first resistor and the fourth diode, between the first node and the first interconnect.

In example 7, the subject matter of example 1, wherein the second interconnect is to communicate a signal, wherein the parasitic BJT circuit structure comprises a collector terminal and an emitter terminal, wherein the third diode is a n-type diode and is coupled to the emitter terminal, and wherein the first interconnect is coupled to the collector terminal.

In example 8, the subject matter of example 7, comprising: a fourth diode coupled in series with the first resistor between the first node and the first interconnect; and a second resistor coupled between the base terminal and the emitter terminal; and an input-output clamp circuit coupled between the first interconnect and the second interconnect.

In example 9, the subject matter of example 1, wherein the second interconnect is to provide a second voltage, wherein the parasitic BJT circuit structure comprises a collector terminal and an emitter terminal, wherein the third diode is a p-type diode and is coupled to the collector terminal, and wherein the first interconnect is coupled to the emitter terminal.

In example 10, the subject matter of example 1, further comprising: a clamp circuit coupled between the first interconnect and the second interconnect, the clamp circuit comprising: two resistor-capacitor (RC) pairs coupled to each other in series and each having a resistor coupled to a capacitor at a common node, and two MOSFETs each having a gate, wherein a different one of the common nodes is coupled to one of the gates; and a first terminal on the second interconnect and coupled to the parasitic BJT circuit structure; a second terminal on the second interconnect and coupled to the clamp circuit; and a second resistor on the second interconnect between the first and second terminals.

In example 11, an apparatus comprises a first interconnect to provide a voltage; a second interconnect; an electrostatic discharge (ESD) clamp structure having a first terminal coupled to the first interconnect and a second terminal coupled to the second interconnect, wherein the ESD clamp structure comprises a parasitic NPN bipolar junction transistor (BJT) circuit structure comprising a base, an emitter terminal, a collector terminal, and anti-parallel first and second diodes each having an anode, wherein the base comprises the anodes; and a third diode having an anode coupled to the second interconnect and a cathode coupled to the collector terminal of the BJT circuit structure.

In example 12, the subject matter of example 11, wherein the ESD clamp structure comprises a shunting capacity of at least 1.3V, and wherein the apparatus comprises at least one semiconductor device coupled to the first and second interconnects and having an operation voltage of 1.2V.

In example 13, the subject matter of example 11 or 12, comprising a first resistor coupled between the base and the first interconnect.

In example 14, the subject matter of example 13, comprising a second resistor and a base diode coupled in series with the second resistor and between the base and the first interconnect, wherein the first resistor is in parallel to the second resistor and the base diode between the base and the first interconnect.

In example 15, a computer implemented system, comprising: memory; and processor circuitry communicatively coupled to the memory, the processor circuitry comprising: a first interconnect to provide a voltage; a second interconnect; a pad-to-VDD (PD) mode electrostatic discharge (ESD) clamp structure arranged to receive a positive current from the second interconnect and having a first terminal coupled to the first interconnect and a second terminal coupled to the second interconnect, wherein the PD mode ESD clamp structure comprises a parasitic NPN bipolar junction transistor (BJT) circuit structure comprising a base, an emitter, a collector, and anti-parallel first and second diodes each having an anode, wherein the base comprises the anodes; and a third diode having an anode coupled to the second interconnect and a cathode coupled to the collector of the BJT circuit structure.

In example 16, the subject matter of example 15, wherein the emitter and the collector each comprise a pair of n-doped regions spaced within an isolated p-type well, and wherein the base comprises a region of the isolated p-type well external to the n-doped regions.

In example 17, the subject matter of example 15, wherein the PD mode ESD clamp structure comprises a triple well having a p-type substrate, a deep n-type well on the p-type substrate, and an isolated p-type well within the deep n-type well.

In example 18, the subject matter of example 17, wherein the PD mode ESD clamp structure comprises a first resistor coupled between the base and the first interconnect, and wherein the deep n-type well is coupled to the first resistor.

In example 19, the subject matter of example 18, wherein the PD mode ESD clamp structure comprising: a second resistor coupled to the base and the first interconnect in parallel to the first resistor; and a fourth diode of the isolated p-type well and deep n-type well and coupled in series to the first resistor between the base and the first interconnect.

In example 20, the subject matter of example 17, wherein the emitter and the collector each comprise a pair of parallel n-doped strips spaced within the isolated p-type well, and wherein the base comprises a region of the isolated p-type well external to the strips, wherein one of the anti-parallel first or second diodes represents a first PN junction between the deep n-type well and the isolated p-type well, and the other of the anti-parallel first or second diodes represents a second PN junction between the deep n-type well and the p-type substrate, wherein the PD mode ESD clamp structure comprises: a p-tap within the isolated p-type well and extending around the strips; an n-tap within the deep n-type well and extending around the isolated p-type well; a first resistor coupled to the p-tap at the isolated p-type well to represent the first resistor being coupled between the base and the first interconnect; and a second resistor coupled to the n-tap at the deep n-type well to represent the second resistor being coupled between the base and the first interconnect in parallel to the first resistor, wherein a fourth diode is in series with the second resistor.

In example 21, a device comprises a first interconnect; a second interconnect to provide a signal; a parasitic bipolar junction transistor (BJT) circuit structure comprising: a metal-oxide semiconductor field effect transistor (MOSFET) first diode, a MOSFET second diode coupled in series with the first diode in an anti-parallel configuration relative to each other, and a first node comprising a base of the BJT circuit structure, wherein the first diode and the second diode are coupled to each other via the first node; a third diode coupled in series to the first and second diodes, coupled to the second interconnect, and having a forward bias to direct forward current away from the BJT circuit structure and to the second interconnect; and a first resistor coupled between the first node and the first interconnect.

In example 22, the subject matter of example 21, wherein the parasitic BJT circuit structure comprises: a first well structure of a first dopant type, wherein the first diode comprises first source or drain regions of a second dopant type and each extending at least partially into the first well structure, and wherein the second diode comprises second source or drain regions extending at least partially into the first well structure, and wherein the second source or drain regions are each of the second dopant type; and a first tap structure extending at least partially into the first well structure, around the first source or drain regions, and around the second source or drain regions, wherein the first tap structure is of the first dopant type.

In example 23, the subject matter of example 22, wherein the parasitic BJT circuit structure comprises: a second well structure extending under and around the first well structure, and having the second dopant type; and a second tap structure extending at least partially into the second well structure and having the second dopant type, wherein the second tap structure extends around the first well structure.

In example 24, the subject matter of example 22, comprising at least one fin of at least one fin field effect transistor (finFET) structure and comprising either (1) the first source or drain regions or (2) the second source or drain regions.

In example 25, the subject matter of any one of examples 21 to 24, wherein the first interconnect is to provide a voltage, wherein the parasitic BJT circuit structure comprises a collector terminal and an emitter terminal, wherein the third diode comprises an n-type MOSFET diode coupled to the emitter terminal, and wherein the first interconnect is coupled to the collector terminal.

In example 26, the subject matter of example 25, comprising: an input-output clamp circuit coupled between the first interconnect and the second interconnect; a fourth diode coupled in series with the first resistor between the first node and the first interconnect; and a second resistor coupled between the first node and the emitter terminal.

In example 27, the subject matter of any one of examples 21 to 26, wherein the parasitic BJT circuit structure is a first BJT circuit structure, and wherein the device comprises an input-output clamp circuit coupled between the first interconnect and the second interconnect and having a parasitic second BJT circuit structure in parallel to the first BJT circuit structure, wherein the second BJT circuit structure comprises a base at a second node, and two anti-parallel diodes coupled to each other via the second node, wherein the input-output clamp circuit comprises a fourth diode having an anode coupled to the second interconnect and a cathode coupled to the second BJT circuit structure.

In example 28, the subject matter of example 27, comprising: a second resistor coupled between the second node and the first interconnect; a fifth diode coupled in series with the second resistor between the second node and the first interconnect; and a third resistor coupled between the second node and the first interconnect in parallel to the second resistor.

In example 29, the subject matter of any one of examples 21 to 28, wherein the parasitic BJT circuit structure comprises a collector, and wherein the first interconnect is coupled to the collector.

In example 30, an apparatus comprising: a first interconnect to provide a voltage; a second interconnect to provide a signal; an electrostatic discharge (ESD) clamp structure having a first terminal coupled to the first interconnect and a second terminal coupled to the second interconnect, wherein the ESD clamp structure comprises a parasitic NPN bipolar junction transistor (BJT) circuit structure comprising a base, an emitter terminal, a collector terminal, and anti-parallel MOSFET first and second diodes each having an anode, wherein the base comprises the anodes; and a third diode having a cathode coupled to the second terminal and an anode coupled to the emitter terminal of the BJT.

In example 31, the subject matter of example 30, wherein the ESD clamp having a shunting capacity of at least 1.3V, and wherein the apparatus comprises at least one semiconductor device coupled to the first and second interconnects and having an operation voltage of 1.2V.

In example 32, the subject matter of example 30 or 31, comprising a first resistor coupled between the base and the emitter terminal.

In example 33, the subject matter of example 30 or 31, comprising: a first resistor node coupled between the BJT and the third diode, and a first resistor coupled between the first resistor node and the base.

In example 34, the subject matter of example 32 or 33, comprising a second resistor and a fourth diode coupled in series with the second resistor and between the base and the first interconnect.

In example 35, a computer implemented system comprises memory; and processor circuitry communicatively coupled to the memory, the processor circuitry comprising: a first interconnect and a second interconnect; a pad-to-VSS (PS) mode electrostatic discharge (ESD) clamp structure arranged to receive negative current from the first interconnect and having a first terminal coupled to the first interconnect and a second terminal coupled to the second interconnect, wherein the PS mode ESD clamp structure comprises a parasitic NPN bipolar junction transistor (BJT) circuit structure comprising a base, an emitter terminal of an emitter, a collector terminal of a collector, and anti-parallel first and second diodes each having an anode, wherein the base comprises the anodes; and a third diode having a cathode coupled to the second interconnect and an anode coupled to the emitter terminal.

In example 36, the subject matter of example 35, wherein the PS mode ESD clamp structure comprises an isolated p-type well, wherein the emitter and collector each comprise a pair of n-doped regions spaced within an isolated p-type well, and wherein the base comprises a region of the isolated p-type well external to the n-doped regions.

In example 37, the subject matter of example 35 or 36, wherein the PS mode ESD clamp structure comprises a triple well having a p-type substrate, a deep n-type well on the p-type substrate, and an isolated p-type well within the deep n-type well.

In example 38, the subject matter of example 37, wherein the PS mode ESD clamp structure comprises a resistor coupled between the base and the first interconnect, and wherein the deep n-type well is coupled to a first resistor.

In example 39, the subject matter of example 38, wherein the PS mode ESD clamp structure comprising: a second resistor coupled to the base and the emitter terminal; and a fourth diode of the isolated p-type well and the deep n-type well and coupled in series to the first resistor between the base and the first interconnect.

In example 40, the subject matter of example 37, wherein the PS mode ESD clamp structure comprises an adjacent p-type well adjacent the deep n-type well, and a p-type doped region within the adjacent p-type well, and wherein the second diode is coupled to the first interconnect via the p-type doped region.

In example 41, an apparatus comprises a first interconnect; a second interconnect; a higher voltage electrostatic discharge (ESD) clamp coupled between the first and second interconnects and comprising a parasitic NPN bipolar junction transistor (BJT) circuit structure, a diode coupled in series with the BJT structure, and a first trigger voltage level to activate the higher voltage ESD clamp; and a lower voltage ESD clamp coupled between the first and second interconnects and having a resistor-capacitor (RC) timer structure coupled to at least two metal-oxide semiconductor field effect transistors (MOSFETs), and a second trigger voltage level less than the first trigger voltage level.

In example 42, the subject matter of example 41, wherein the higher voltage ESD clamp comprises a first node on the second interconnect, wherein the lower voltage ESD clamp comprises a second node on the second interconnect, and wherein the second interconnect comprises a first resistor coupled between the first and second nodes.

In example 43, the subject matter of example 41 or 42, wherein the RC timer structure comprises two RC pairs coupled to each other in series, wherein each RC pair has a resistor coupled to a capacitor in series.

In example 44, the subject matter of example 43, wherein each RC pair has a first node coupling the resistor of the RC pair to the capacitor of the RC pair, and wherein each of two of the at least two MOSFET has a gate coupled to a different one of the first nodes.

In example 45, the subject matter of example 44, wherein the lower voltage ESD clamp comprises a second node coupling the two MOSFETs in series, and wherein the two MOSFETS comprise a first MOSFET having a body coupled to the second interconnect, and a second MOSFET having a body coupled to the second node.

In example 46, the subject matter of any one of examples 41 to 45, wherein the second trigger voltage level at least partially depends on a time constant of the RC timer structure.

In example 47, the subject matter of any one of examples 41 to 46, wherein the second trigger voltage level depends at least partially on a slew rate of the MSOFETs. In example 48, the subject matter of any one of examples 41 to 47, wherein the first trigger voltage level is equal to or greater than 4V, and the second trigger voltage level is less than 4V including zero.

In example 49, the subject matter of any one of examples 41 to 48, wherein the BJT circuit structure comprises a base having a first node and anti-parallel first and second diodes coupled in series via the first node, and a first resistor coupled between the first node and the first interconnect.

In example 50, a computer implemented system comprises memory; processor circuitry communicatively coupled to the memory, the processor circuitry comprising: first circuitry comprising a first interconnect and a second interconnect; second circuitry coupled to the first and second interconnects and comprising a first electrostatic discharge (ESD) clamp comprising a parasitic NPN bipolar junction transistor (BJT) circuit structure, a diode electrically coupled in series with the BJT circuit structure, and a first trigger current level to activate the first ESD clamp; and third circuitry coupled to the first and second interconnects in parallel to the first ESD clamp and comprising a second ESD clamp having a resistor-capacitor (RC) timer structure, at least two metal-oxide semiconductor field effect transistors (MOSFETs) coupled to the RC timer structure, and a second trigger current level less than the first trigger current level.

In example 51, the subject matter of example 50, wherein the first ESD clamp is a pad-to-VDD (PD) ESD clamp and comprises a resistor coupled to a base of the BJT circuit structure and the first interconnect, and wherein the diode comprises a forward bias from the second interconnect to the BJT circuit structure, and the first ESD clamp.

In example 52, the subject matter of example 51, wherein the first circuitry comprises at least one semiconductor device operating at a voltage of 3.3 volts, and wherein the resistor comprises a resistance of 10 Ohms.

In example 53, the subject matter of any one of examples 50 to 52, wherein the at least two MOSFETs are p-type.

In example 54, the subject matter of any one of examples 50 to 53, wherein the second ESD clamp comprises two of the at least two MOSFETs coupled to each other and each having a gate, and wherein the RC timer structure comprises two RC pairs having a first node between the resistor and capacitor on each RC pair, wherein each first node is coupled to a gate of one of the two MOSFETs.

In example 55, the subject matter of any one of examples 50 to 54 wherein the first trigger current level is at least 6.5 A, and the second trigger current level is at most 1.5 A,

In example 56, an apparatus comprises a first interconnect; a second interconnect having first and second nodes; a first electrostatic discharge (ESD) clamp coupled between the first interconnect and the first node, and having a parasitic NPN bipolar junction transistor (BJT) circuit structure, a first diode coupled in series with the BJT circuit structure, and a first trigger voltage level to activate the higher voltage ESD clamp; and a second ESD clamp coupled between the first interconnect and the second node, and having two resistor-capacitor (RC) pairs coupled to each other in series, wherein each RC pair has a resistor coupled to a capacitor in series, and two field effect transistors each coupled to one of the RC pairs, and wherein the second ESD clamp has a second trigger voltage level less than the first trigger voltage level; and a first resistor coupled to the second interconnect between the first and second nodes.

In example 57, the subject matter of example 16, comprising at least one first circuitry coupled to the first and second interconnects and in parallel to the first and second ESD clamps, wherein the first circuitry comprises a second diode with a forward bias direction from the first interconnect and toward the second interconnect.

In example 58, the subject matter of example 57, wherein the first circuitry is coupled to the second interconnect between the first ESD clamp and the first resistor.

In example 59, the subject matter of example 57 comprising two first circuitries with the first ESD clamp being coupled to the second interconnect between the two first circuitries.

In example 60, the subject matter of any one of examples 57 to 59 comprising two first circuitries with one of the first circuitries having an implicit diode and the other of the two first circuitries having an explicit diode.

In example 61, a device or system includes a memory and processor circuitry to perform a method of ESD protection with structure of any one of the above examples.

In example 62, at least one machine readable medium includes a plurality of instructions that in response to being executed on a computing device, cause the computing device to perform a method of ESD protection with structure of any one of the above examples.

In example 63, an apparatus may include means for performing a method of ESD protection with structure of any one of the above examples.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

What is claimed is:

1. A device comprising:
a first interconnect to provide a voltage;
a second interconnect;
a parasitic bipolar junction transistor (BJT) circuit structure comprising a metal-oxide semiconductor field effect transistor (MOSFET) first diode and a MOSFET second diode coupled in series with the first diode in an anti-parallel configuration relative to each other, and a first node, wherein the first diode and the second diode are coupled to each other via the first node, and wherein the first node provides a base terminal of the parasitic BJT circuit structure;
a third diode coupled between the second interconnect and the parasitic BJT circuit structure; and
a first resistor coupled between the first node and the first interconnect.

2. The device of claim 1, wherein the parasitic BJT circuit structure comprises:
a first well structure of a first dopant type, wherein the first diode comprises first source or drain regions of a second dopant type and each extending at least partially into the first well structure, and wherein the second diode comprises second source or drain regions extending at least partially into the first well structure, and wherein the second source or drain regions are each of the second dopant type; and
a first tap structure extending at least partially into the first well structure, around the first source or drain regions, and around the second source or drain regions, wherein the first tap structure is of the first dopant type.

3. The device of claim 2, wherein the parasitic BJT circuit structure comprises:
a second well structure extending under and around the first well structure, and having the second dopant type; and
a second tap structure extending at least partially into the second well structure and having the second dopant type, wherein the second tap structure extends around the first well structure.

4. The device of claim 2, comprising at least one fin structure of at least one fin field effect transistor (finFET) comprising at least one fin having either (1) the first source or drain regions or (2) the second source or drain regions.

5. The device of claim 1, wherein the second interconnect is to communicate a signal, wherein the parasitic BJT circuit structure comprises a collector terminal and an emitter terminal, wherein the third diode comprises a p-type diode coupled to the collector terminal, and wherein the first interconnect is coupled to the emitter terminal.

6. The device of claim 5, comprising:
an input-output clamp circuit coupled between the first interconnect and the second interconnect;
a fourth diode coupled in series with the first resistor between the first node and the first interconnect; and
a second resistor coupled, in parallel with the first resistor and the fourth diode, between the first node and the first interconnect.

7. The device of claim 1, wherein the second interconnect is to communicate a signal, wherein the parasitic BJT circuit structure comprises a collector terminal and an emitter terminal, wherein the third diode is a n-type diode and is coupled to the emitter terminal, and wherein the first interconnect is coupled to the collector terminal.

8. The device of claim 7, comprising:
a fourth diode coupled in series with the first resistor between the first node and the first interconnect; and
a second resistor coupled between the base terminal and the emitter terminal; and
an input-output clamp circuit coupled between the first interconnect and the second interconnect.

9. The device of claim 1, wherein the second interconnect is to provide a second voltage, wherein the parasitic BJT circuit structure comprises a collector terminal and an emitter terminal, wherein the third diode is a p-type diode and is coupled to the collector terminal, and wherein the first interconnect is coupled to the emitter terminal.

10. The device of claim 1, further comprising:
a clamp circuit coupled between the first interconnect and the second interconnect, the clamp circuit comprising:
two resistor-capacitor (RC) pairs coupled to each other in series and each having a resistor coupled to a capacitor at a common node, and
two MOSFETs each having a gate, wherein a different one of the common nodes is coupled to one of the gates; and
a first terminal on the second interconnect and coupled to the parasitic BJT circuit structure;
a second terminal on the second interconnect and coupled to the clamp circuit; and
a second resistor on the second interconnect between the first and second terminals.

11. An apparatus comprising:
a first interconnect to provide a voltage;
a second interconnect;
an electrostatic discharge (ESD) clamp structure having a first terminal coupled to the first interconnect and a second terminal coupled to the second interconnect, wherein the ESD clamp structure comprises a parasitic NPN bipolar junction transistor (BJT) circuit structure comprising a base, an emitter terminal, a collector terminal, and anti-parallel first and second diodes each having an anode, wherein the base comprises the anodes; and
a third diode having an anode coupled to the second interconnect and a cathode coupled to the collector terminal of the BJT circuit structure.

12. The apparatus of claim 11, wherein the ESD clamp structure comprises a shunting capacity of at least 1.3V, and wherein the apparatus comprises at least one semiconductor device coupled to the first and second interconnects and having an operation voltage of 1.2V.

13. The apparatus of claim 11, comprising a first resistor coupled between the base and the first interconnect.

14. The apparatus of claim 13, comprising a second resistor and a base diode coupled in series with the second resistor and between the base and the first interconnect, wherein the first resistor is in parallel to the second resistor and the base diode between the base and the first interconnect.

15. A computer implemented system, comprising:
memory; and
processor circuitry communicatively coupled to the memory, the processor circuitry comprising:
a first interconnect to provide a voltage;
a second interconnect;
a pad-to-VDD (PD) mode electrostatic discharge (ESD) clamp structure arranged to receive a positive current from the second interconnect and having a first terminal coupled to the first interconnect and a second terminal coupled to the second interconnect, wherein the PD mode ESD clamp structure comprises a parasitic NPN bipolar junction transistor (BJT) circuit structure comprising a base, an emitter, a collector, and anti-parallel first and second diodes each having an anode, wherein the base comprises the anodes; and
a third diode having an anode coupled to the second interconnect and a cathode coupled to the collector of the BJT circuit structure.

16. The system of claim 15, wherein the emitter and the collector each comprise a pair of n-doped regions spaced within an isolated p-type well, and wherein the base comprises a region of the isolated p-type well external to the n-doped regions.

17. The system of claim 15, wherein the PD mode ESD clamp structure comprises a triple well having a p-type substrate, a deep n-type well on the p-type substrate, and an isolated p-type well within the deep n-type well.

18. The system of claim 17, wherein the PD mode ESD clamp structure comprises a first resistor coupled between the base and the first interconnect, and wherein the deep n-type well is coupled to the first resistor.

19. The system of claim 18, wherein the PD mode ESD clamp structure comprising:
a second resistor coupled to the base and the first interconnect in parallel to the first resistor; and
a fourth diode of the isolated p-type well and deep n-type well and coupled in series to the first resistor between the base and the first interconnect.

20. The system of claim 17, wherein the emitter and the collector each comprise a pair of parallel n-doped strips spaced within the isolated p-type well, and wherein the base comprises a region of the isolated p-type well external to the strips,
wherein one of the anti-parallel first or second diodes represents a first PN junction between the deep n-type well and the isolated p-type well, and the other of the anti-parallel first or second diodes represents a second PN junction between the deep n-type well and the p-type substrate,
wherein the PD mode ESD clamp structure comprises:
a p-tap within the isolated p-type well and extending around the strips;
an n-tap within the deep n-type well and extending around the isolated p-type well;
a first resistor coupled to the p-tap at the isolated p-type well to represent the first resistor being coupled between the base and the first interconnect; and
a second resistor coupled to the n-tap at the deep n-type well to represent the second resistor being coupled between the base and the first interconnect in parallel to the first resistor,
wherein a fourth diode is in series with the second resistor.
